(19) United States
(12) Patent Application Publication
(10) Pub. No.: US 2014/0069568 A1
(43) Pub. Date: Mar. 13, 2014

(54) REDUCED CONTACT ROLL-TO-ROLL PROCESSING

(71) Applicant: APPLE INC., Cupertino, CA (US)

(72) Inventors: Siddharth MOHAPATRA, Santa Clara, CA (US); Sunggu Kang, San Jose, CA (US); John Z. Zhong, Cupertino, CA (US)

(73) Assignee: Apple Inc., Cupertino, CA (US)

(21) Appl. No.: 13/710,354

(22) Filed: Dec. 10, 2012

Related U.S. Application Data
(60) Provisional application No. 61/699,118, filed on Sep. 10, 2012.

(51) Int. Cl. H05K 13/02; H05K 13/04

(52) U.S. Cl. CPC H05K 13/02; H05K 13/04
USPC 156/64; 193/37; 156/358

(57) ABSTRACT

Processes for reducing physical contact to sheets of base film in roll-to-roll processing of touch sensors are disclosed. In one example, the process includes the use of rollers having rings circumferentially extending away from the roller and operable to contact the sheets of base film. The rings can be configured to contact portions of the sheet of base film away from touch sensor areas of the base film. The rings can further be configured to prevent the sheets of base film from contacting a shaft of the rollers. In another example, a reduced strength vacuum seal can be formed between a photo mask and the sheet of base film to reduce the amount of force applied to a passivation layer of the sheet of base film.

### FIELD

This relates generally to touch sensors and, more specifically, to reduced contact processes for manufacturing touch sensors.

### BACKGROUND

Many types of input devices are presently available for performing operations in a computing system, such as buttons or keys, mice, trackballs, joysticks, touch sensor panels, touch screens, and the like. Touch sensitive devices, such as touch screens, in particular, are becoming increasingly popular because of their ease and versatility of operation. A touch sensitive device can include a touch sensor panel, which can be a clear panel with a touch-sensitive surface, and a display device, such as a liquid crystal display (LCD) or organic light emitting diode (OLED) display, that can be positioned partially or fully behind the panel so that the touch-sensitive surface can cover at least a portion of the viewable area of the display device. The touch sensitive device can allow a user to perform various functions by touching the touch sensor panel using a finger, stylus, or other object at a location often dictated by a user interface (UI) being displayed by the display device. In general, the touch sensitive device can recognize a touch event and the position of the touch event on the touch sensor panel, and the computing system can then interpret the touch event in accordance with the display appearing at the time of the touch event, and thereafter can perform one or more actions based on the touch event.

Many processes have been developed to manufacture these touch sensors. For example, conventional roll-to-roll processes involve patterning electronic devices onto rolls of thin, flexible plastic or metal foil. These devices can then be removed from the roll using lithography or a physical cutting process. These roll-to-roll processes can reduce the amount of time and money required to manufacture touch sensors. However, when using rolls of plastic material in conventional roll-to-roll processing systems, the plastic material can be susceptible to particle defects due to the soft nature of the plastic. For example, small particles located on the rollers of the roll-to-roll system can introduce defects into the surface of the plastic film. Thus, improved touch sensor manufacturing systems and processes are desired.

### SUMMARY

This relates to systems and processes for reducing physical contact to sheets of base film in roll-to-roll processing of touch sensors. In one example, the process includes the use of rollers having rings circumferentially extending away from the roller and operable to contact the sheets of base film. The rings can be configured to contact portions of the sheet of base film away from touch sensor areas of the base film. The rings can further be configured to prevent the sheets of base film from contacting a shaft of the rollers. In another example, a reduced strength vacuum seal can be formed between a photo mask and the sheet of base film to reduce the amount of force applied to a passivation layer of the sheet of base film.

### BRIEF DESCRIPTION OF THE DRAWINGS

FIG. 1 illustrates an exemplary touch sensor according to various examples.

FIG. 2 illustrates an exemplary mother sheet containing multiple touch sensors according to various examples.

FIG. 3 illustrates a side view of an exemplary roll-to-roll processing system according to various examples.

FIG. 4 illustrates an exemplary roller for a roll-to-roll processing system.

FIG. 5 illustrates an exemplary roller having rings for a roll-to-roll processing system according to various examples.

FIG. 6 illustrates another exemplary roller having rings for a roll-to-roll processing system according to various examples.

FIG. 7 shows an image of an exemplary roller having rings for a roll-to-roll processing system according to various examples.

FIG. 8 illustrates an exemplary process for manufacturing touch sensors in a roll-to-roll processing system according to various examples.

FIG. 9 illustrates an exemplary touch sensor according to various examples.

FIG. 10 illustrates an exemplary process for manufacturing touch sensors using a reduced strength vacuum seal according to various examples.

FIG. 11 illustrates an exemplary touch sensor having a protective film according to various examples.

FIG. 12 illustrates an exemplary system for manufacturing touch sensors according to various examples.

FIGS. 13-16 illustrate exemplary personal devices having a touch sensor manufactured according to various examples.

### DETAILED DESCRIPTION

In the following description of the disclosure and examples, reference is made to the accompanying drawings in which it is shown by way of illustration specific examples that can be practiced. It is to be understood that other examples can be practiced and structural changes can be made without departing from the scope of the disclosure.

Various examples related to systems and processes for reducing physical contact to sheets of base film in roll-to-roll processing of touch sensors are disclosed. In one example, the process includes the use of rollers having rings circumferentially extending away from the roller and operable to contact the sheets of base film. The rings can be configured to contact portions of the sheet of base film away from touch sensor areas of the base film. The rings can further be configured to prevent the sheets of base film from contacting a shaft of the rollers. In another example, a reduced strength vacuum seal can be formed between a photo mask and the sheet of base film to reduce the amount of force applied to a passivation layer of the sheet of base film.

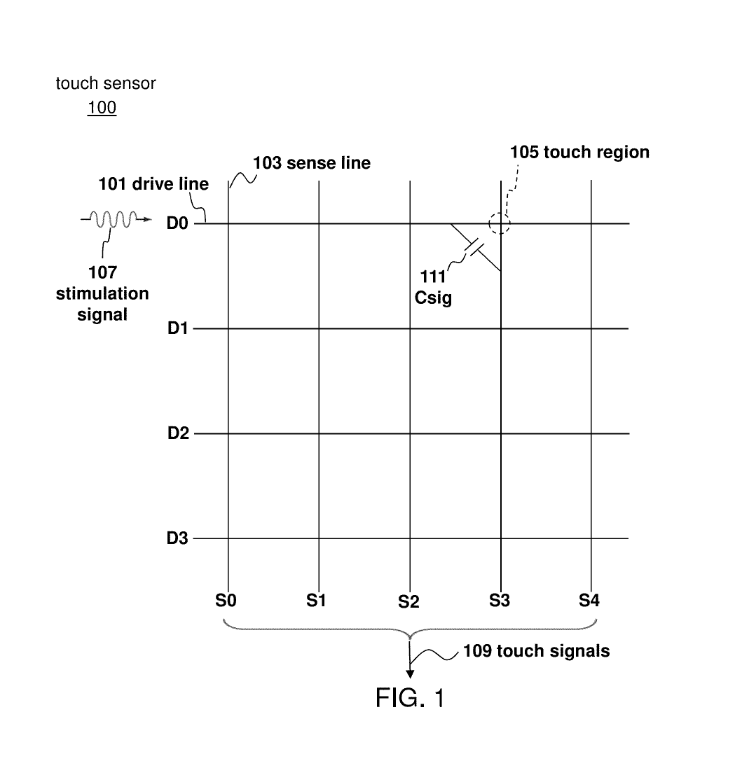

FIG. 1 illustrates touch sensor 100 that can be used to detect touch events on a touch sensitive device, such as a mobile phone, tablet, touchpad, portable computer, portable media player, or the like. Touch sensor 100 can include an array of touch regions or nodes 105 that can be formed at the crossing points between rows of drive lines 101 (D0-D3) and columns of sense lines 103 (S0-S4). Each touch region 105 can have an associated mutual capacitance Csig 111 formed between the crossing drive lines 101 and sense lines 103 when the drive lines are stimulated. The drive lines 101 can be stimulated by stimulation signals 107 provided by drive circuitry (not shown) and can include an alternating current (AC) waveform. The sense lines 103 can transmit touch signals 109 indicative of a touch at the touch sensor 100 to sense circuitry (not shown), which can include a sense amplifier for each sense line, or a fewer number of sense amplifiers that can be multiplexed to connect to a larger number of sense lines.

To sense a touch at the touch sensor 100, drive lines 101 can be stimulated by the stimulation signals 107 to capacitively couple with the crossing sense lines 103, thereby forming a capacitive path for coupling charge from the drive lines 101 to the sense lines 103. The crossing sense lines 103 can output touch signals 109, representing the coupled charge or current. When an object, such as a stylus, finger, etc., touches the touch sensor 100, the object can cause the capacitance Csig 111 to reduce by an amount ΔCsig at the touch location. This capacitance change ΔCsig can be caused by charge or current from the stimulated drive line 101 being shunted through the touching object to ground rather than being coupled to the crossing sense line 103 at the touch location. The touch signals 109 representative of the capacitance change ΔCsig can be transmitted by the sense lines 103 to the sense circuitry for processing. The touch signals 109 can indicate the touch region where the touch occurred and the amount of touch that occurred at that touch region location.

While the example shown in FIG. 1 includes four drive lines 101 and five sense lines 103, it should be appreciated that touch sensor 100 can include any number of drive lines 101 and any number of sense lines 103 to form the desired number and pattern of touch regions 105. Additionally, while the drive lines 101 and sense lines 103 are shown in FIG. 1 in a crossing configuration, it should be appreciated that other configurations are also possible to form the desired touch region pattern. While FIG. 1 illustrates mutual capacitance touch sensing, other touch sensing technologies may also be used in conjunction with examples of the disclosure, such as self-capacitance touch sensing, resistive touch sensing, projection scan touch sensing, and the like. Furthermore, while various examples describe a sensed touch, it should be appreciated that the touch sensor 100 can also sense a hovering object and generate hover signals therefrom.

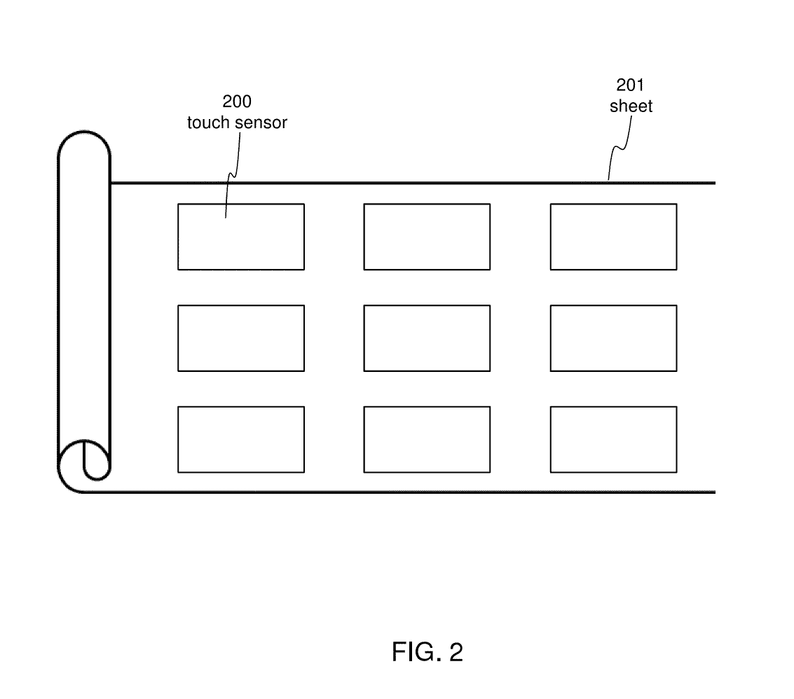

Touch sensors, such as touch sensor 100, can be manufactured in various ways. For example, touch sensors can be manufactured using a roll-to-roll process that involves patterning the touch sensor onto rolls of thin, flexible plastic or metal foil. These devices can then be removed from the roll using lithography or a physical cutting process. To illustrate, FIG. 2 shows multiple touch sensors 200 similar or identical to touch sensor 100 formed on a sheet of base film 201. In some examples, the sheet of base film 201 can include a malleable material or a flexible plastic material, such as cyclo olefin polymer (COP). In these examples, the drive lines, sense lines, bond pads, metal traces, and the like, of the touch sensor 200 can be formed by etching the COP material. Once the touch sensors 200 are patterned onto the sheet of base film 201, the touch sensors can be cut from the sheet of base film 201, producing individual touch sensors 200.

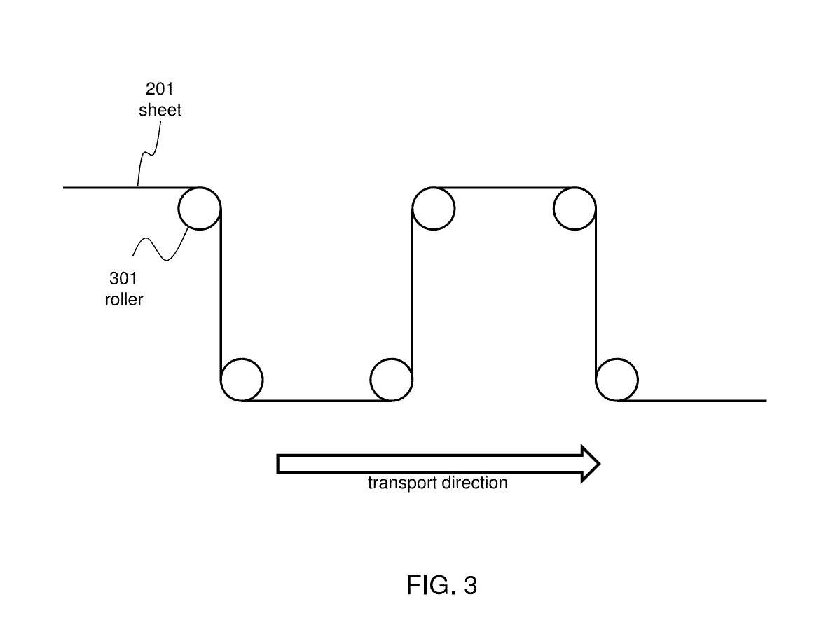

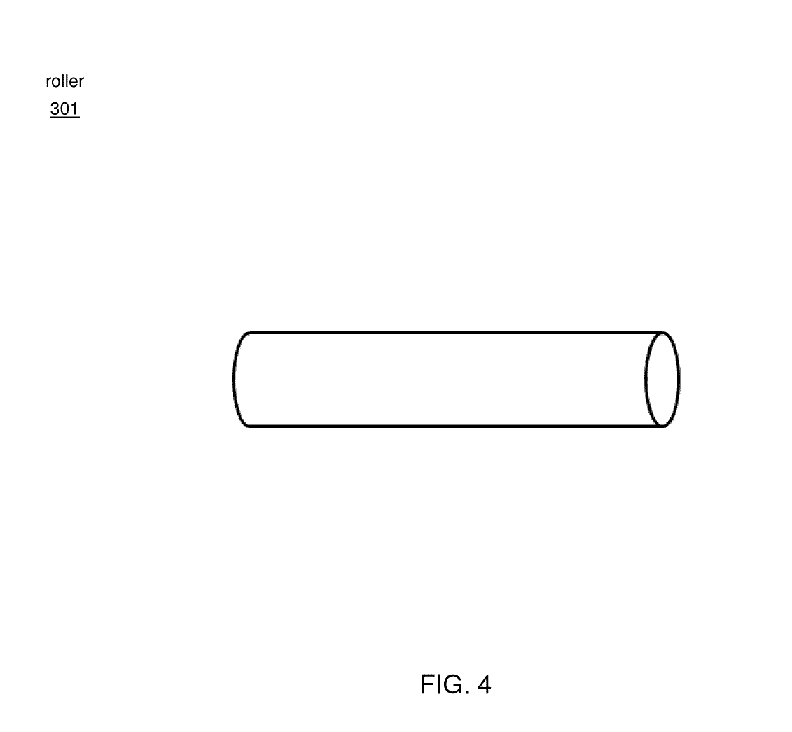

During the roll-to-roll process described above, the sheet of base film 201 can be transported over multiple rollers to move, shape, and position the sheet of base film 201 for use in the manufacturing process. For example, FIG. 3 shows the sheet of base film 201 traveling over multiple rollers 301. An example roller 301 is shown in FIG. 4. In the roller system shown in FIG. 3, when a sheet of base film 201 is made from a soft material, such as COP, the film 201 can be easily damaged by the rollers 301. For example, small particles on the surface of the rollers can cause indentations or deformations in the film 201 as the sheet travels over the surface of the roller 301. This can result in both cosmetic defects and functional defects if the coatings or patterns on the film 201 are damaged.

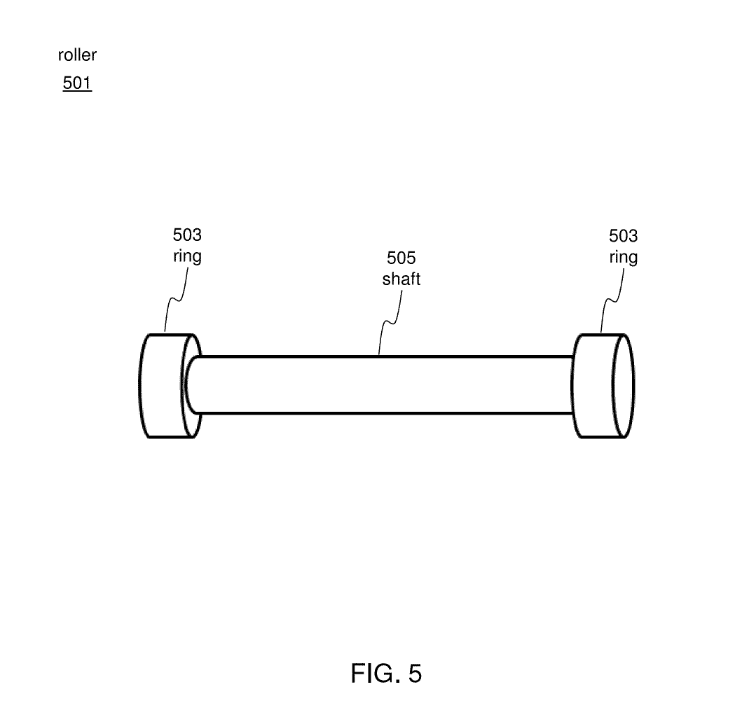

To prevent or reduce the damage caused by the rollers in a roll-to-roll process, rollers having rings according to various examples of the present disclosure can be used. For example, FIG. 5 illustrates an exemplary roller 501 having rings 503 at the ends of the center shaft 505. Using this configuration, the contact area between the sheet of base film 201 and rollers 501 can be reduced, thereby reducing the risk of damaging the film 201. For example, the rings 503 can be positioned on rollers 501 such that they would contact portions of sheet 201 on which no touch sensors 200 would be formed. Thus, particles or other imperfections on the surface of rings 503 would not affect the portions of film 201 that will eventually be included within touch sensors 200. The width and clearance height (e.g., difference between the radius of ring 503 and shaft 505) can be varied based on the particular application. For example, different widths and clearance heights can be used depending on the width of the sheet of base film 201, stiffness of the sheet of base film 201, speed at which the sheet of base film 201 travels over roller 501, the tension of the sheet of base film 201, and the like. In general, the ring widths can be configured such that the rings themselves do not damage the sheet of base film 201 by stretching or otherwise deforming the sheet. Additionally, the clearance heights can be configured such that the sheet of base film 201 does not contact shaft 505 between rings 503 due to slack in the sheet of base film 201. One of ordinary skill, given the present disclosure, can calculate or experimentally determine appropriate dimensions for rollers 501 for a particular type of base film 201 in a particular processing environment.

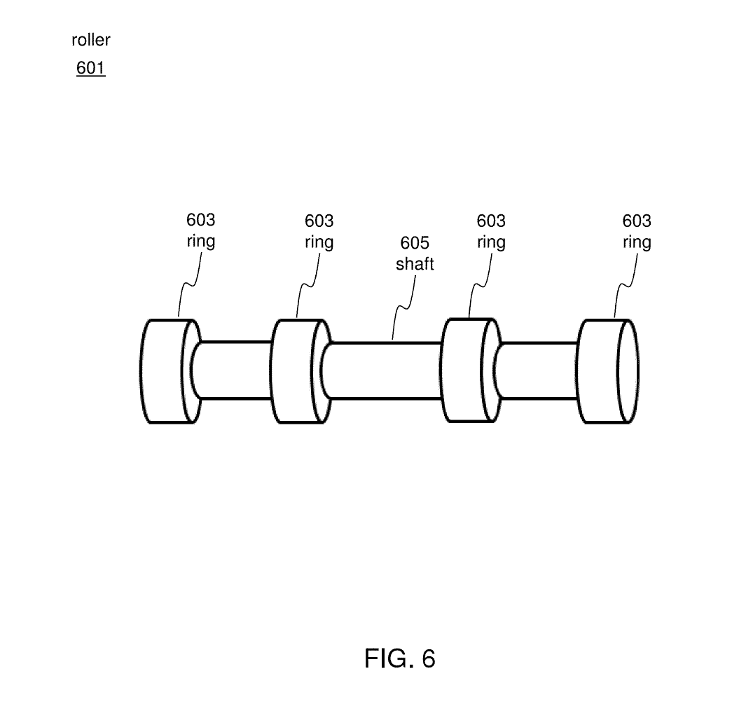

In some examples, shaft 505 and rings 503 can be made from a plastic or metal material. However, other types of rigid materials can be used. Shaft 505 and rings 503 can be separate elements, with rings attached to shaft 505. Alternatively, shaft 505 and rings 503 can form a unitary body. In some examples, the roller can include more than two rings. For example, FIG. 6 illustrates an exemplary roller 601 having four rings 603 coupled to shaft 605. The multiple rings can be equidistant or non-equidistantly spaced. Roller 601 can be used to reduce or prevent damage to the sheet of base film 201 in a similar manner as roller 501. Specifically, rings 603 can reduce the contact area between the sheet of base film 201 and the roller 601, thereby reducing the risk of damage to the sheet of base film 201. Like roller 501, rings 603 can be positioned such that they contact portions of the sheet of base film 201 away from the locations where touch sensors 200 were/will be formed. Thus, particles or other imperfections on the surface of rings 603 would not affect the portions of the sheet of base film 201 that will eventually be included within touch sensors 200. The width and clearance height (e.g., difference between the radius of ring 603 and shaft 605) can be varied based on the particular application. For example, different widths and clearance heights can be used depending on the width of the sheet of base film 201, stiffness of the sheet of base film 201, speed at which the sheet of base film 201 travels over roller 601, the tension of the sheet of base film 201, and the like. In general, the ring widths can be configured such that the rings themselves do not damage the sheet of base film 201 by stretching or otherwise deforming the sheet. Additionally, the clearance heights can be configured such that the sheet of base film 201 does not contact shaft 605 between rings 603 due to slack in sheet of base film 201. One of ordinary skill, given the present disclosure, can calculate or experimentally determine appropriate dimensions for rollers 601 for a particular type of base film 201 in a particular processing environment.

Rollers 501 and 601 described above can be used as any type of roller in a roll-to-roll system. For example, rollers 501 and 601 can be used as transportation, idling, dancer, tension, or nip rollers in a roll-to-roll processing system.

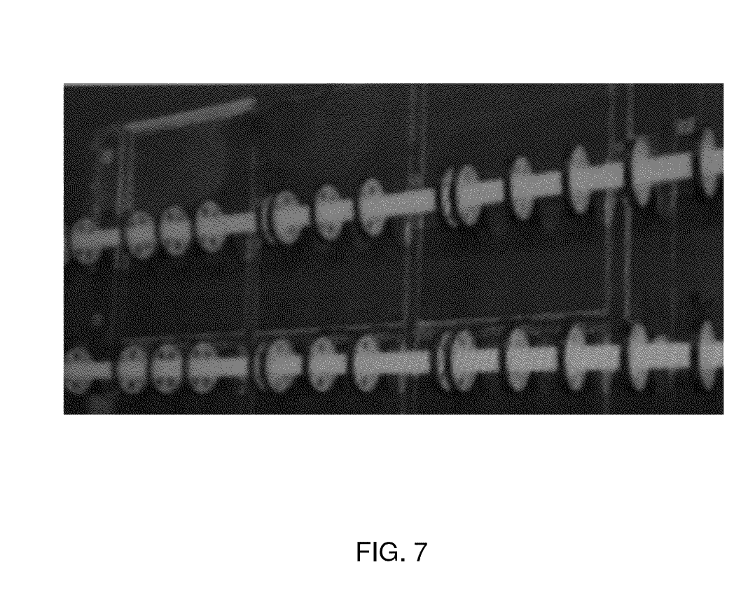

While the examples described above include rollers having 2 and 4 rings, it should be appreciated that any number of rings can be attached to the rollers (e.g., as illustrated by the image shown in FIG. 7). Using additional rings can allow lower clearance heights for the rings since there are additional intermediate rings between the edges of the sheet of base film 201. However, additional rings can increase the contact area between the rings and the sheet of base film 201. Thus, when designing the rollers, a balance can be struck between reducing the clearance height of the rings and the amount of contact area between the rings and the sheet of base film 201.

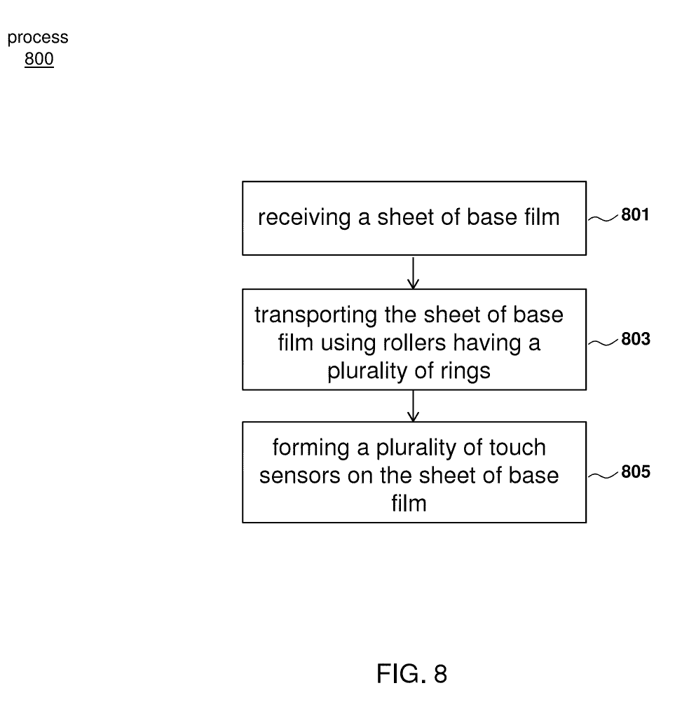

FIG. 8 illustrates an exemplary process 800 for manufacturing touch sensors in a roll-to-roll processing system. At block 801, a sheet of base film is received. In some examples, the sheet of base film can be similar or identical to the sheet of base film 201. In particular, the sheet of base film can be formed from a malleably or soft material, such as plastic or COP.

At block 803, the sheet of base film can be transported using rollers having a plurality of rings. In some examples, rollers similar or identical to rollers 501 or 601 can be used to transport the sheet of base film received at block 801. The rollers can include any number of rings circumferentially extending away from the shaft of the roller. As described above with respect to FIGS. 5-7, the roller's rings can be configured such that they do not contact portions of the sheet of base film where touch sensors will be formed. Additionally, the rollers and rings can be configured such that the sheet of base film will not contact the shaft of the roller between rings.

At block 805, a plurality of touch sensors can be formed on the sheet of base film. In some examples, the touch sensors can be formed on the sheet of base film in a manner similar or identical to that described above with respect to touch sensors 200 and film 201. In particular, the touch sensors can be formed on the sheet of base film using any known patterning technique, such as deposition or photolithography. In some examples, at least a portion of the formation of the touch sensors at block 805 can be performed at the same time as the operation performed at block 803. For instance, the sheet of base film can be transported by the rollers while portions of the touch sensors are being deposited or otherwise formed on the sheet of base film.

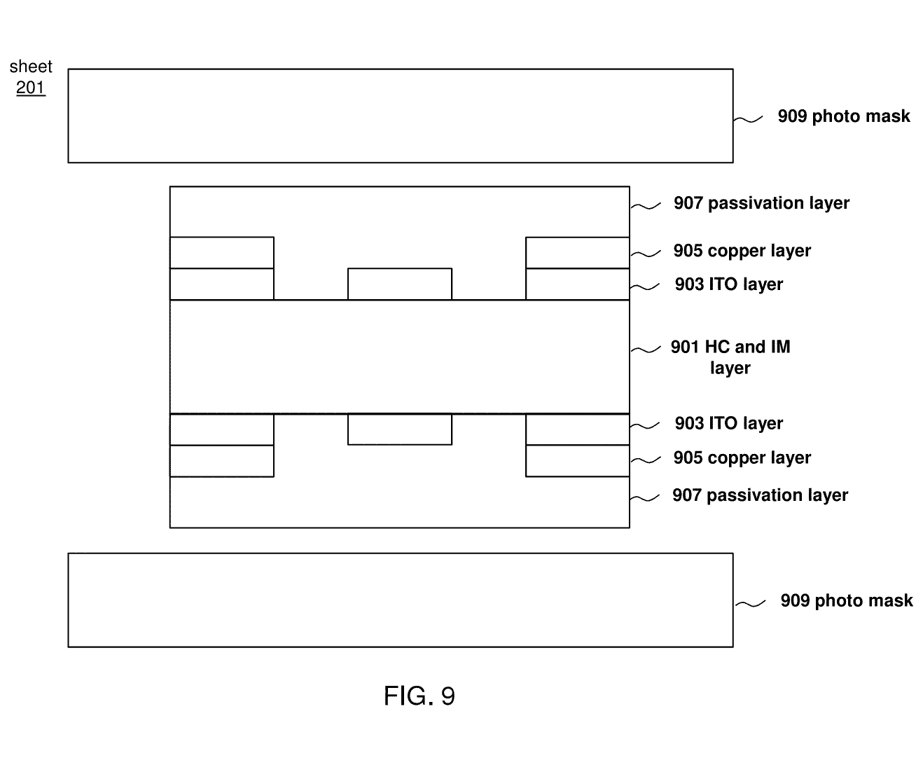

In the roll-to-roll processes described above, a layer of transparent dry film resist (DFR) can be used as a passivation layer in the viewing area of a touch sensor. For example, FIG. 9 shows an example touch sensor being formed on the sheet of base film 201. In this example, the sheet of base film 201 includes a flexible plastic material, such as COP, having a hard-coat (HC) layer, index matching (IM) layer, indium tin oxide (ITO) layer 903, and copper layer 905. The HC layer and IM layer have been combined into a single HC and IM layer 901 for simplicity, but it should be appreciated that these layers can be separate layers. A layer of DFR has also been deposited on the COP film as passivation layer 907. A photo mask 909 can then be held against passivation layer 907 using a vacuum seal around the edge of the photo mask 909.

In some instances, the DFR passivation layer 907 can be soft and weak prior to a UV curing process. As a result, the DFR passivation layer 907 can be susceptible to damage from the physical contact with photo mask 909. For example, similar to the process using rollers, particles on photo mask 909 can damage the surface of the passivation layer 907 during contact.

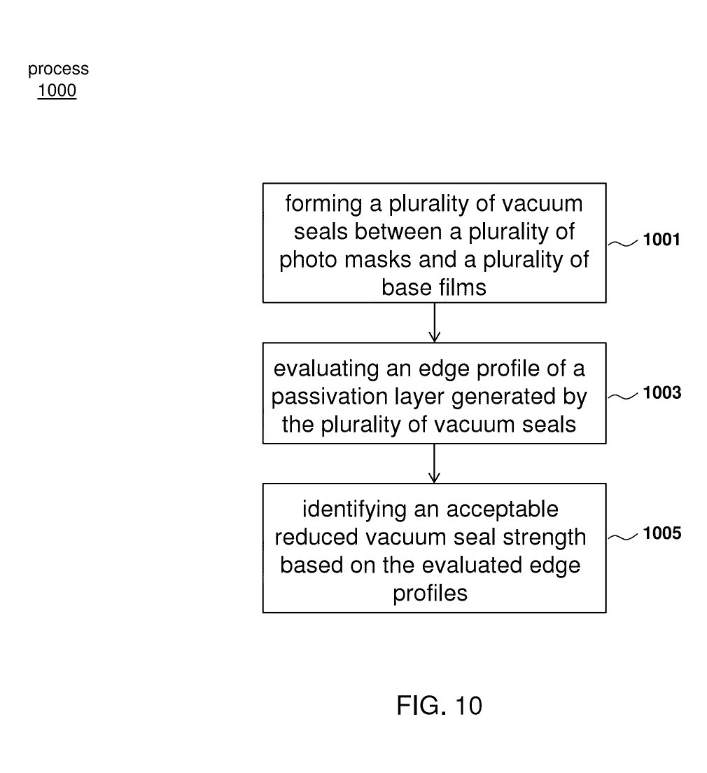

To prevent or reduce the damage caused by photo mask 909 to passivation layer 907, exemplary process 1000 for determining a reduced strength seal, as shown in FIG. 10, can be performed. At block 1001, a plurality of vacuum seals can be formed between a plurality of photo masks and a plurality of base films. For example, multiple vacuum seals of varying strengths can be formed between photo masks similar or identical to photo mask 909 and sheets of base films similar or identical to base film 201. In this way, different seal strengths can be formed between similar photo masks and similar base films.

At block 1003, an edge profile of a passivation layer generated by the plurality of vacuum seals can be evaluated. For example, edge profiles of passivation layers similar or identical to passivation layers 907 can be evaluated. The profile of the passivation layer can depend on the seal strength applied to the passivation layer by the seal formed at block 1001. Generally, a higher seal strength will generate a flatter edge profile, while a lower seal strength will generate a more wavy edge profile of the passivation layer.

At block 1005, an acceptable reduced vacuum seal strength can be identified based on the evaluated edge profiles. For example, based on the edge profiles of passivation layers 907 evaluated at block 1003, a minimum acceptable edge profile can be identified. The minimum acceptable edge profile can be determined using criteria dependent on the application of the touch sensor being formed. The vacuum strength that generated the minimum acceptable edge profile can be identified as the acceptable reduced vacuum seal strength.

The reduced vacuum seal strength identified at block 1005 can then be used in future manufacturing processes using the photo mask and base films used at blocks 1001 and 1003. In this way, the damage caused by the photo mask to the passivation layer can be eliminated or reduced by reducing the force applied to the passivation layer by the photo mask to an amount that is sufficient to produce an acceptable touch sensor. This is in contrast to conventional methods where the vacuum seal is set to the highest obtainable value to produce more desirable passivation edge profiles.

In some examples, the processes described above with respect to FIGS. 3-8 can be combined with the processes described with respect to FIGS. 9-10 to improve the yield of roll-to-roll processes. For example, the processes described with respect to FIGS. 9-10 can be performed during the photo mask portions of the roll-to-roll process, while the processes described above with respect to FIGS. 3-8 can be performed during the remaining portions of the roll-to-roll process.

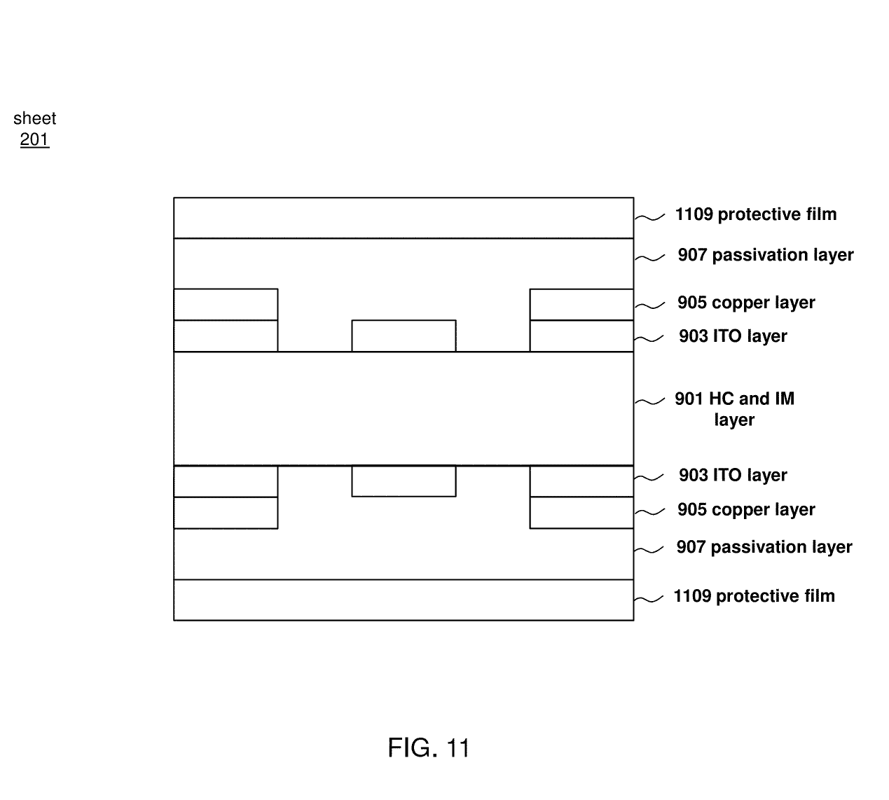

Alternatively, in other examples, a protective film can be applied to the passivation layer of the touch sensor. For example, FIG. 11 shows a protective film 1109 applied to passivation layer 907. Protective film 1109 can be adhered to passivation layer 907 using a pressure sensitive adhesive (PSA). Protective film 1109 and the PSA can protect the soft passivation layer 907 by absorbing physical contact that would otherwise contact passivation layer 907. The material and thickness of the protective film 1109 and PSA can vary depending on the protective film and PSA used, the force applied to the protective film by external objects, the shape of the external objects, and the like.

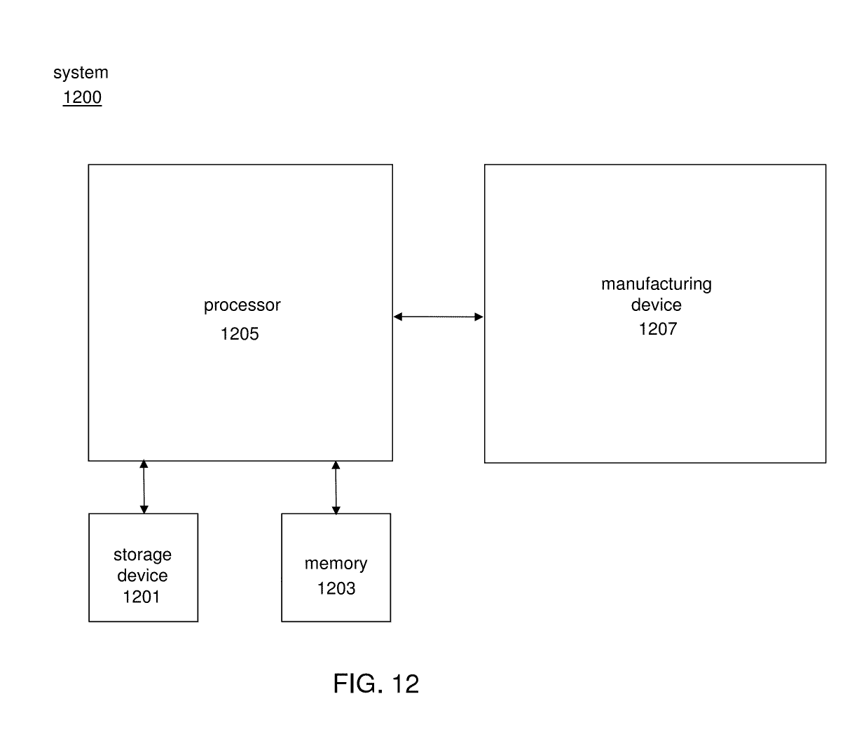

One or more of the functions relating to the manufacturing of a touch sensitive device described above can be performed by a system similar or identical to system 1200 shown in FIG. 12. System 1200 can include instructions stored in a non-transitory computer readable storage medium, such as memory 1203 or storage device 1201, and executed by processor 1205. The instructions can also be stored and/or transported within any non-transitory computer readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “non-transitory computer readable storage medium” can be any medium that can contain or store the program for use by or in connection with the instruction execution system, apparatus, or device. The non-transitory computer readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The instructions can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport medium can include, but is not limited to, an electronic, magnetic, optical, electromagnetic or infrared wired or wireless propagation medium.

System 1200 can further include manufacturing device 1207 coupled to processor 1205. Manufacturing device 1207 can be operable to transport a sheet of base film using rollers similar or identical to those described above with respect to FIGS. 3-8 and apply vacuums of varying levels using a vacuum as described above with respect to FIGS. 9-10. Processor 1205 can control manufacturing device 1207 and its components to generate a desired pattern of metal traces, drive lines, sense lines, and bond pads in a manner similar or identical to that described above.

It is to be understood that the system is not limited to the components and configuration of FIG. 12, but can include other or additional components in multiple configurations according to various examples. Additionally, the components of system 1200 can be included within a single device, or can be distributed between two manufacturing device 1207, in some examples, processor 1205 can be located within manufacturing device 1207.

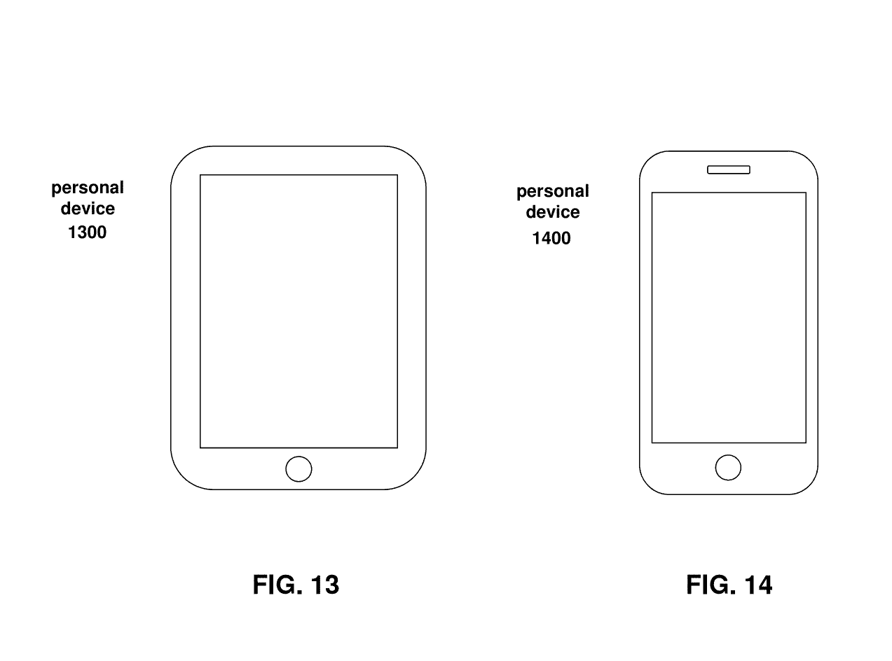

FIG. 13 illustrates an exemplary personal device 1300, such as a tablet, that can include a touch sensor manufactured using the processes described above.

FIG. 14 illustrates another exemplary personal device 1400, such as a mobile phone, that can include a touch sensor manufactured using the processes described above.

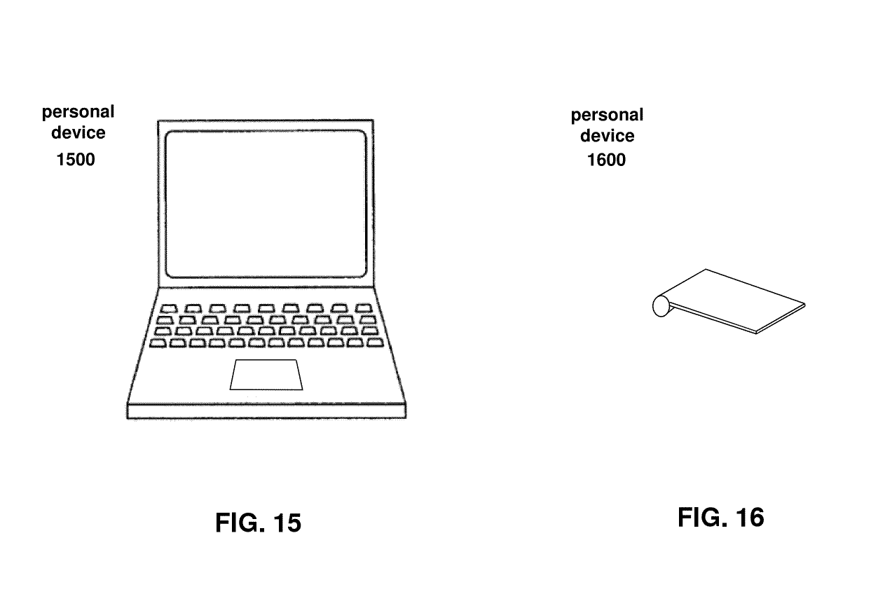

FIG. 15 illustrates an exemplary personal device 1500, such as a laptop having a touchpad that can include a touch sensor manufactured using the processes described above.

FIG. 16 illustrates another exemplary personal device 1600, such as a touch pad, that can include a touch sensor manufactured using the processes described above.

Therefore, according to the above, some examples of the disclosure are directed to an apparatus for roll-to-roll processing for a touch sensor, the apparatus comprising: a plurality of rollers for transporting a plastic sheet through the apparatus, wherein each of the plurality of rollers comprises a plurality of rings circumferentially extending away from the roller and operable to contact the plastic sheet, and wherein the plurality of rings are positioned to contact the plastic sheet away from a touch sensor area of the plastic sheet. Additionally or alternatively to one or more of the examples disclosed above, the plurality of rings can be equidistantly separated. Additionally or alternatively to one or more of the examples disclosed above, the plurality of rollers can comprise one or more of transportation, idling, dancer, tension, or nip rollers. Additionally or alternatively to one or more of the examples disclosed above, the touch sensor area of the plastic sheet can correspond to an area of the plastic sheet at which a touch sensor is to be formed. Additionally or alternatively to one or more of the examples disclosed above, the touch sensor area of the plastic sheet can comprise a touch sensor. Additionally or alternatively to one or more of the examples disclosed above, the plurality of rings can be configured to prevent the plastic sheet from contacting a shaft portion of the plurality of rollers.

Some examples of the disclosure are directed to a method for roll-to-roll processing for a touch sensor, the method comprising: transporting a malleable sheet using a plurality of rollers, wherein each of the plurality of rollers comprises a plurality of rings circumferentially extending away from the roller; and contacting the sheet with plurality of rings, wherein the plurality of rings prevent the malleable sheet from contacting a shaft portion of the roller. Additionally or alternatively to one or more of the examples disclosed above, the plurality of rollers can be positioned to contact the malleable sheet away from a touch sensor area of the malleable sheet. Additionally or alternatively to one or more of the examples disclosed above, the method can further include forming a touch sensor within the touch sensor area of the malleable sheet. Additionally or alternatively to one or more of the examples disclosed above, the plurality of rollers can comprise plastic or metal.

Some examples of the disclosure are directed to a method comprising: forming a plurality of vacuum seals between a plurality of photo masks and a plurality of sheets of base film, wherein the plurality of vacuum seals have varying strengths; evaluating edge profiles of a plurality of passivation layers of the plurality of sheets of base film generated by the plurality of vacuum seals; and identifying an acceptable reduced vacuum seal strength based on the evaluated edge profiles. Additionally or alternatively to one or more of the examples disclosed above, the plurality of sheets of base film can comprise cyclo olefin polymer. Additionally or alternatively to one or more of the examples disclosed above, the acceptable reduced vacuum seal strength can correspond to a vacuum seal of the plurality of vacuum seals that produced a minimum acceptable edge profile of the plurality of passivation layers. Additionally or alternatively to one or more of the examples disclosed above, the method can further include manufacturing a plurality of touch sensors using the identified acceptable reduced vacuum seal strength. Additionally or alternatively to one or more of the examples disclosed above, the method can further include transporting the plurality of sheets of base film using a plurality of rollers, wherein each of the plurality of rollers comprises a plurality of rings circumferentially extending away from the roller and operable to contact the plurality of sheets of base film, and wherein the plurality of rings prevent the plurality of sheets of base film from contacting a shaft portion of the roller.

Some examples of the disclosure are directed to an apparatus comprising: a vacuum operable to form a vacuum seal between a photo mask and a sheet of base film; and a controller operable to cause the vacuum to generate the vacuum seal having an acceptable reduced vacuum seal strength, wherein the acceptable reduced vacuum seal strength is selected to generate a desired edge profile of a passivation layer of the sheet of base film. Additionally or alternatively to one or more of the examples disclosed above, the passivation layer can comprise a dry film resist. Additionally or alternatively to one or more of the examples disclosed above, the desired edge profile of the passivation layer of the sheet of base film can represent a minimum acceptable edge profile of the passivation layer. Additionally or alternatively to one or more of the examples disclosed above, the acceptable reduced vacuum seal strength can be determined based at least in part on a plurality of previous vacuum seals formed between a plurality of photo masks and a plurality of sheets of base film. Additionally or alternatively to one or more of the examples disclosed above, the apparatus can further include a plurality of rollers for transporting the sheet of base film through the apparatus, wherein each of the plurality of rollers comprises a plurality of rings circumferentially extending away from the roller and operable to contact the sheet of base film, and wherein the plurality of rings are positioned to contact the sheet of base film away from a touch sensor area of the sheet of base film.

Although the disclosure and examples have been fully described with reference to the accompanying drawings, it is to be noted that various changes and modifications will become apparent to those skilled in the art. Such changes and modifications are to be understood as being included within the scope of the disclosure and examples as defined by the appended claims.

What is claimed is:

1. An apparatus for roll-to-roll processing for a touch sensor, the apparatus comprising:
a plurality of rollers for transporting a plastic sheet through the apparatus, wherein each of the plurality of rollers comprises a plurality of rings circumferentially extending away from the roller and operable to contact the plastic sheet, and wherein the plurality of rings are positioned to contact the plastic sheet away from a touch sensor area of the plastic sheet.

2. The apparatus of claim 1, wherein the plurality of rings are equidistantly separated.

3. The apparatus of claim 1, wherein the plurality of rollers comprise one or more of transportation, idling, dancer, tension, or nip rollers.

4. The apparatus of claim 1, wherein the touch sensor area of the plastic sheet corresponds to an area of the plastic sheet at which a touch sensor is to be formed.

5. The apparatus of claim 1, wherein the touch sensor area of the plastic sheet comprises a touch sensor.

6. The apparatus of claim 1, wherein the plurality of rings are configured to prevent the plastic sheet from contacting a shaft portion of the plurality of rollers.

7. A method for roll-to-roll processing for a touch sensor, the method comprising:
transporting a malleable sheet using a plurality of rollers, wherein each of the plurality of rollers comprises a plurality of rings circumferentially extending away from the roller; and
contacting the sheet with plurality of rings, wherein the plurality of rings prevent the malleable sheet from contacting a shaft portion of the roller.

8. The method of claim 7, wherein the plurality of rollers are positioned to contact the malleable sheet away from a touch sensor area of the malleable sheet.

9. The method of claim 8, further comprising forming a touch sensor within the touch sensor area of the malleable sheet.

10. The method of claim 7, wherein the plurality of rollers comprise plastic or metal.

11. A method comprising:
forming a plurality of vacuum seals between a plurality of photo masks and a plurality of sheets of base film, wherein the plurality of vacuum seals have varying strengths;
evaluating edge profiles of a plurality of passivation layers of the plurality of sheets of base film generated by the plurality of vacuum seals; and
identifying an acceptable reduced vacuum seal strength based on the evaluated edge profiles.

12. The method of claim 11, wherein the plurality of sheets of base film comprise cyclo olefin polymer.

13. The method of claim 11, wherein the acceptable reduced vacuum seal strength corresponds to a vacuum seal of the plurality of vacuum seals that produced a minimum acceptable edge profile of the plurality of passivation layers.

14. The method of claim 11 further comprising manufacturing a plurality of touch sensors using the identified acceptable reduced vacuum seal strength.

15. The method of claim 11 further comprising transporting the plurality of sheets of base film using a plurality of rollers, wherein each of the plurality of rollers comprises a plurality of rings circumferentially extending away from the roller and operable to contact the plurality of sheets of base film, and wherein the plurality of rings prevent the plurality of sheets of base film from contacting a shaft portion of the roller.

16. An apparatus comprising:
a vacuum operable to form a vacuum seal between a photo mask and a sheet of base film; and
a controller operable to cause the vacuum to generate the vacuum seal having an acceptable reduced vacuum seal strength, wherein the acceptable reduced vacuum seal strength is selected to generate a desired edge profile of a passivation layer of the sheet of base film.

17. The apparatus of claim 16, wherein the passivation layer comprises a dry film resist.

18. The apparatus of claim 16, wherein the desired edge profile of the passivation layer of the sheet of base film represents a minimum acceptable edge profile of the passivation layer.

19. The apparatus of claim 16, wherein the acceptable reduced vacuum seal strength is determined based at least in part on a plurality of previous vacuum seals formed between a plurality of photo masks and a plurality of sheets of base film.

20. The apparatus of claim 16, further comprising a plurality of rollers for transporting the sheet of base film through the apparatus, wherein each of the plurality of rollers comprises a plurality of rings circumferentially extending away from the roller and operable to contact the sheet of base film, and wherein the plurality of rings are positioned to contact the sheet of base film away from a touch sensor area of the sheet of base film.
